(19) United States
(12) Patent Application Publication
(10) Pub. No.: US 2012/0256152 A1
(43) Pub. Date: Oct. 11, 2012

(54) SEMICONDUCTOR DEVICE AND METHOD FOR MANUFACTURING THE SAME

(75) Inventor: Tomoyasu KAKEGAWA, Tokyo (JP)

(73) Assignee: ELPIDA MEMORY, INC., Tokyo (JP)

(21) Appl. No.: 13/441,554

(22) Filed: Apr. 6, 2012

(30) Foreign Application Priority Data
Apr. 7, 2011 (JP) 2011-085635

(51) Int. Cl. H01L 47/00; H01L 21/336

(52) U.S. Cl. 257/2; 438/238; 257/E47.001; 257/E21.409

(57) ABSTRACT

A method for manufacturing a semiconductor device includes: forming a first insulating film that covers a substrate; forming a conductive plug that penetrates the first insulating film; forming a hole portion on the conductive plug by partly removing upper part of the conductive plug, wherein the hole portion has a top surface of the conductive plug as a bottom surface, and has the first insulating film of a portion that covered the partly removed conductive plug as a sidewall; forming a sidewall insulating film that exposes a part of the bottom surface of the hole portion while covering the sidewall of the hole portion and a bottom portion of the hole portion; forming a variable resistance film that covers the sidewall insulating film and the bottom surface of the hole portion; and forming a conductive film that covers the variable resistance film.

### TECHNICAL FIELD

### Reference to Related Application

This application is based upon and claims the benefit of the priority of Japanese patent application No. 2011-085635, filed on Apr. 7, 2011, the disclosure of which is incorporated herein in its entirety by reference thereto.

This invention relates to a semiconductor device including ReRAM (Resistance Random Access Memory) and a method for manufacturing the same, and particularly relates to the semiconductor device and the method for manufacturing the same.

### BACKGROUND

In recent years, ReRAM as shown in FIGS. 9A and 9B has been focused on as a next generation non-volatile memory cell (refer to Non-Patent Document 1). ReRAM has an element structure which is a laminated structure consisting of metal film 101/variable resistance film 102/metal film 103, and is a semiconductor memory in which a significant change of an electric resistance (CER (Colossal Electro Resistance) effect) caused by applying a voltage is used. A resistance that is in a low resistance state is called a set resistance; whereas a resistance that is in a high resistance state is called a reset resistance.

A method for operating a ReRAM will be described by referring to FIGS. 10A and 10B (refer to Non-Patent Document 1). First, in initial state where a current path is not formed in the variable resistance film 102, a current path 121 conducting between the metal film 101 and the metal film 103 is formed in the variable resistance film 102 by applying a high voltage between the metal film 101 and the metal film 103 to transit the variable resistance film 102 to a low resistance state (Forming). After that, a switching from a low resistance state to a high resistance state (Reset) and a switching from a high resistance state to a low resistance state (Set) are controlled by magnitude of applied voltage. A Set voltage is higher than a Reset voltage. When transiting from a low resistance state to a high resistance state, a rupture portion 122 that ruptures at a portion near the metal film 103 of the current path 121 is formed. When transiting from a high resistance state to a low resistance state, the rupture portion 122 that has ruptured at a portion near the metal film 103 vanishes, so that the current path 121 conducting between the metal film 101 and the metal film 103 is formed.

As shown in FIG. 11A, it is ideally preferable that a single current path is formed when Forming. However, as shown in FIG. 11B, current paths that are formed in a practical situation are formed at various positions in the variable resistance film 102, which includes incomplete current paths 123, and particularly current paths are likely to be formed near sidewalls of the variable resistance film 102 that suffer an etching damage (see current paths 124 near the sidewall). In a switching operation after the Forming, if the incomplete current path 123 is conductive, the resistance value is lowered rapidly, which causes a malfunction. Besides, since a switching characteristics of the current path 124 near the sidewall of the variable resistance film 102 that suffers the damage is different from that of the current path 121 near the central portion that does not suffer the damage, the switching characteristics of the current path 124 causes an extremely increased variability in performance or an extreme deterioration in reliability of memory elements.

In order to solve this problem, a structure has been proposed in which current paths formed in a resistance change film (variable resistance film) when forming the current paths (Forming) are limited by forming a sidewall insulator by means of oxidizing a lower electrode and an upper electrode from the sides in a state where a hard mask used for forming a MIM structure, in which the lower electrode, the variable resistance film, and the upper electrode are laminated, is not removed (see FIGS. 7E, 7F of Patent Document 1). Patent Document 1 describes that this makes it possible to prevent the current paths in the variable resistance film from being dispersedly formed, so that a stable Set/Reset operation can be realized. Particularly, Patent Document 1 describes that it is effective that the sidewall portions of the lower electrode and the upper electrode including portions that suffer etching damage are changed to be inactive by means of oxidizing the sidewall portions.

### Patent Document 1

JP Patent Kokai Publication No. JP-P2000-133775A

### Non-Patent Document 1

Akihito Sawa, “Resistive switching in transition metal oxides”, Materials Today, Volume 11, Number 6, 28-36 (June 2008).

### SUMMARY

The disclosure of above patent document and non-patent document are incorporated herein by reference thereto in their entirety. The following analysis is given by the present invention. According to the structure described in Patent Document 1, it is possible that forming current paths near the sidewalls that suffer etching damage (corresponding to 124 in FIGS. 11A and 11B) can be prevented. However, since parts of the lower electrode and the upper electrode are changed to insulators (sidewall insulator) by oxidizing, control fluctuation in the oxidized amount causes variability in performance of memory elements. In other words, there is possibility that incomplete current paths (corresponding to 123 in FIGS. 11A and 11B) are formed due to control fluctuation in the oxidized amount. That is, the variability in thickness of an oxidized film affects forming current paths (Forming), which causes variability in characteristics of memory elements.

Thus, the conventional semiconductor device including ReRAM had a risk of causing variability in characteristics of memory elements.

In a first aspect of the present disclosure, there is provided a method for manufacturing a semiconductor device, comprising: forming a first insulating film that covers a substrate; forming a conductive plug(s) that penetrates the first insulating film; forming a hole portion(s) on the conductive plug(s) by partly removing upper part(s) of the conductive plug(s). The hole portion(s) has a top surface(s) of the conductive plug(s) as a bottom surface(s) of the hole portion(s), and has the first insulating film of a portion(s) that covered the partly removed conductive plug(s) as a sidewall(s) of the hole portion(s). The method further comprises: forming a sidewall insulating film(s) that exposes a part of the bottom surface(s) of the hole portion(s) while covering the sidewall(s) and a bottom portion(s) of the hole portion(s); forming a variable resistance film that covers the sidewall insulating film(s) of the hole portion(s) and the bottom surface(s) of the hole portion(s); and forming a conductive film that covers the variable resistance film.

In a second aspect of the present disclosure, there is provided a semiconductor device, comprising: a first insulating film that covers a substrate; a conductive plug(s) that is embedded between a bottom surface of the first insulating film and a position of a predetermined depth from a top surface of the first insulating film at a predetermined region(s) of the first insulating film; a hole portion(s) on the conductive plug(s) that has a top surface(s) of the conductive plug(s) as a bottom surface(s) of the hole portion(s), and has the first insulating film as a sidewall(s) of the hole portion(s) at a region(s) in which the conductive plug(s) is disposed. The semiconductor device further comprises: a sidewall insulating film(s) that covers the sidewall(s) of the hole portion(s), and covers a part of the bottom surface(s) of the hole portion(s); a variable resistance film that covers the sidewall insulating film(s) and the bottom surface(s) of the hole portion(s); and a conductive film that covers the variable resistance film.

In a third aspect of the present invention, there is provided a semiconductor device, comprising: a first insulating film that covers a substrate; a conductive plug(s) that is embedded between a bottom surface of the first insulating film and a predetermined position of the first insulating film at a predetermined region(s) of the first insulating film; a hole portion(s) on the conductive plug(s) that has a top surface(s) of the conductive plug(s) as a bottom surface(s) of the hole portion(s) and the first insulating film as a sidewall(s) of the hole portion(s) at a region(s) in which the conductive plug(s) is disposed. The semiconductor device further comprises: a sidewall insulating film(s) that covers the sidewall(s) of the hole portion(s), and covers a part of the bottom surface(s) of the hole portion(s); a variable resistance film that conformally covers the sidewall insulating film(s) and the bottom surface(s) of the hole portion(s); and a conductive film that covers the variable resistance film.

In a fourth aspect of the present disclosure, there is provided a semiconductor device, comprising: a hole portion(s), at a region(s) in which a conductive plug(s) is disposed, having a top surface(s) of the conductive plug(s) as a bottom surface(s) of the hole portion(s), and having an insulating film in which the conductive plug(s) is formed as a sidewall(s) of the hole portion(s); a sidewall insulating film(s) that covers the sidewall(s) of the hole portion(s), and covers part(s) of the bottom surface(s) of the hole portion(s); a variable resistance film that covers the sidewall insulating film(s) and the bottom surface(s) of the hole portion(s); and a conductive film that covers the variable resistance film.

As a result, it is not likely to generate dispersed current paths when Forming, which makes it possible to avoid variability in characteristics of the elements, so that a Set/Reset operation of ReRAM can be stabilized.

### BRIEF DESCRIPTION OF THE DRAWINGS

FIGS. 1A and 1B are respectively a plan view and a cross-sectional view taken along the line X-X′ schematically showing a structure of a semiconductor device in accordance with an exemplary embodiment of the present invention.

FIGS. 2A and 2B are respectively a plan view and a cross-sectional view taken along the line X-X′ schematically showing a first step of a method for manufacturing a semiconductor device in accordance with the exemplary embodiment of the present invention.

FIGS. 3A and 3B are respectively a plan view and a cross-sectional view taken along the line X-X′ schematically showing a second step of a method for manufacturing a semiconductor device in accordance with the exemplary embodiment of the present invention.

FIGS. 4A and 4B are respectively a plan view and a cross-sectional view taken along the line X-X′ schematically showing a third step of a method for manufacturing a semiconductor device in accordance with the exemplary embodiment of the present invention.

FIGS. 5A and 5B are respectively a plan view and a cross-sectional view taken along the line X-X′ schematically showing a fourth step of a method for manufacturing a semiconductor device in accordance with the exemplary embodiment of the present invention.

FIGS. 6A and 6B are respectively a plan view and a cross-sectional view taken along the line X-X′ schematically showing a fifth step of a method for manufacturing a semiconductor device in accordance with the exemplary embodiment of the present invention.

FIGS. 7A and 7B are respectively a plan view and a cross-sectional view taken along the line X-X′ schematically showing a sixth step of a method for manufacturing a semiconductor device in accordance with the exemplary embodiment of the present invention.

FIGS. 8A and 8B are respectively a plan view and a cross-sectional view taken along the line X-X′ schematically showing a seventh step of a method for manufacturing a semiconductor device in accordance with the exemplary embodiment of the present invention.

FIG. 9A is a schematic view showing a structure of a typical ReRAM memory cell; FIG. 9B is a schematic view showing a CER effect of a ReRAM memory cell.

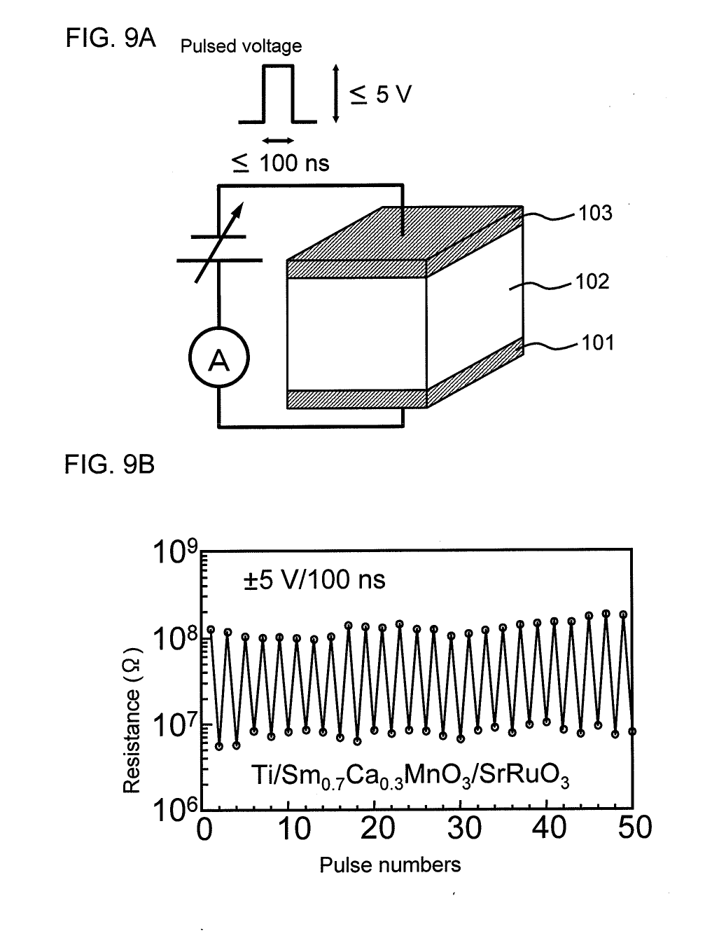

FIGS. 10A and 10B are respectively a schematic view showing a change of voltage-current characteristics of each of processes and a schematic view showing a current path of each of the processes in a operating manner of a ReRAM memory cell.

FIGS. 11A and 11B are respectively illustrations of an ideal state and a real state schematically showing a current path when Forming process for a ReRAM memory cell.

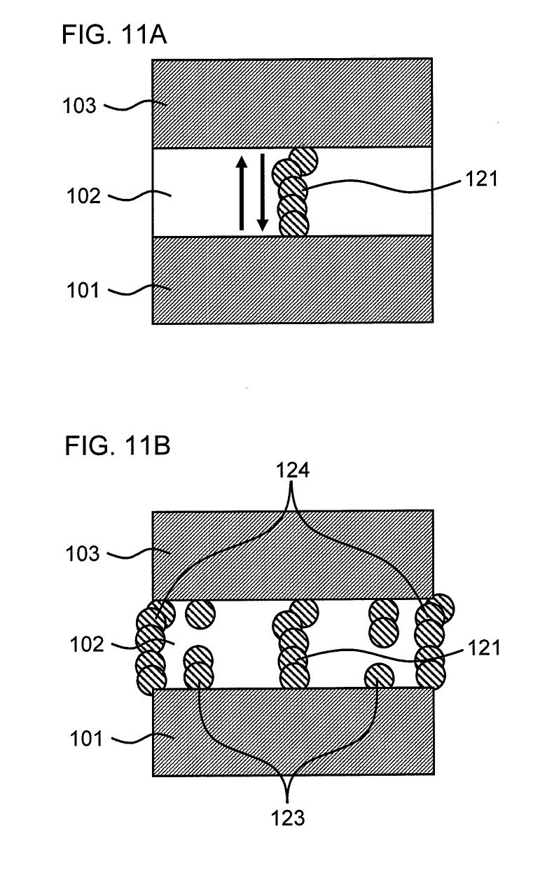

FIGS. 12A and 12B are respectively a plan view and a cross-sectional view taken along the line X-X′ schematically showing a structure of a semiconductor device that has been considered in advance by the present inventor.

FIGS. 13A, 13B and 13C are cross-sectional views schematically showing some principal steps of a method for manufacturing a semiconductor device shown in FIGS. 12A and 12B.

FIGS. 14A and 14B are respectively a plan view and a cross-sectional view taken along the line X-X′ schematically showing a structure of another semiconductor device that has been considered in advance by the present inventor.

FIGS. 15A, 15B and 15C are cross-sectional views schematically showing some principal steps of a method for manufacturing a semiconductor device shown in FIGS. 14A and 14B.

FIGS. 16A and 16B are cross-sectional views schematically showing some principal steps of a method for manufacturing a semiconductor device shown in FIGS. 14A and 14B, which is a continuation of FIGS. 15A, 15B and 15C.

### PREFERRED MODES

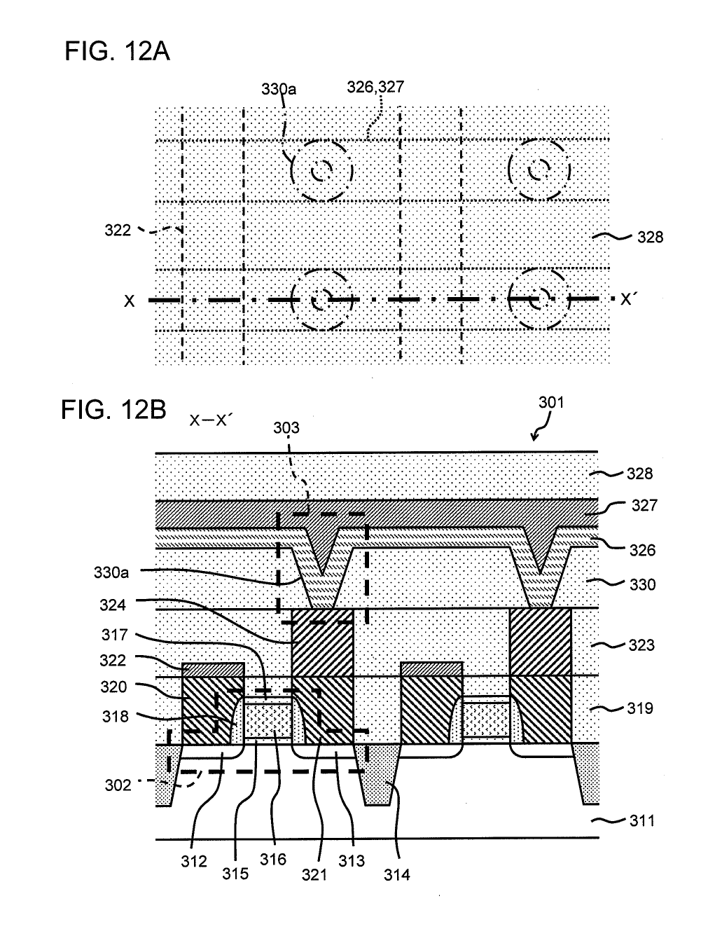

According to viewpoint of the present inventor, in order to avoid variability in characteristics of memory elements in a semiconductor device including ReRAM, it is necessary that an area of a variable resistance film sandwiched between electrodes is small (narrowed) without oxidizing sidewall portions of an upper electrode and a lower electrode. From the viewpoint, the present inventor considered a variable resistance element having a structure that will be described below by referring to FIGS. 12A to 16B.

In a variable resistance element 303 shown in FIGS. 12A and 12B, base hole 330a with a taper shape (shape in which the width becomes narrower as approaching a plug 324) reaching the plug 324 is formed in an interlayer insulating film 330 on the plug 324 that serves as a lower electrode; a variable resistance film 326 is formed so that the base hole 330a is not completely filled on the interlayer insulating film 330 including the plug 324 exposed from the base hole 330a and a sidewall of the base hole 330a; a bit line wiring 327 that serves as an upper electrode is formed on the variable resistance film 326. Part of the variable resistance film 326 is structured to be embedded into the base hole 330a. The bit line wiring 327 that serves as an upper electrode is embedded into on the variable resistance 326 at the base hole 330a.

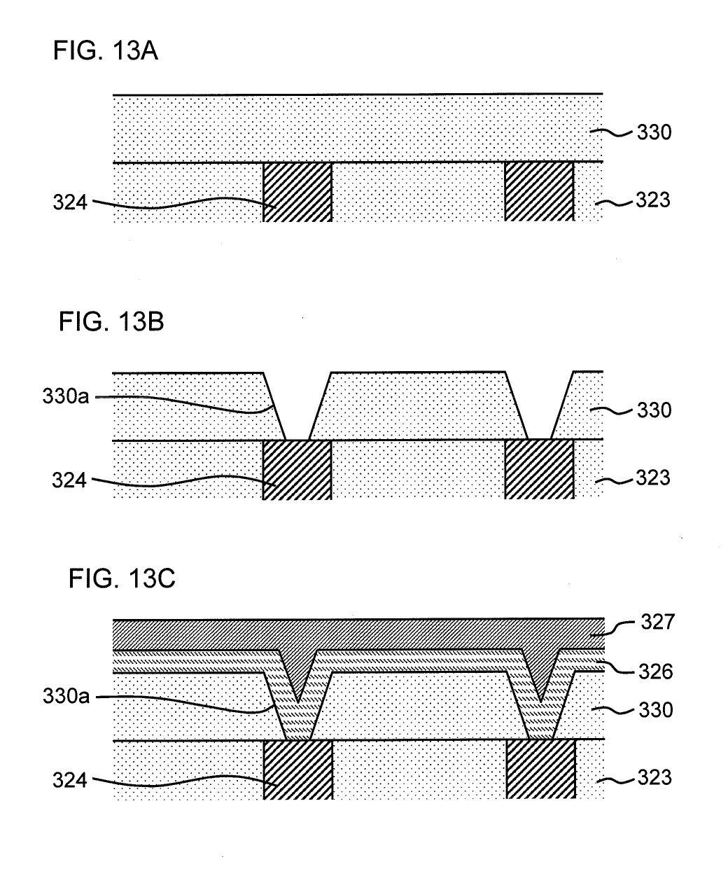

The variable resistance element 303 having a structure as shown in FIGS. 12A and 12B can be formed as follows. First, by means of a known method, a semiconductor substrate 311, on which element isolation regions 314, transistors 302, an interlayer insulating film 319, source/drain plugs 320, 321, source wirings 322, an interlayer insulating film 323, and plugs 324 are formed, is provided. After that, an interlayer insulating film 330 is deposited on the interlayer insulating film 323 including the plugs 324 (see FIG. 13A); base holes 330a with a taper shape reaching the plugs 324 in the interlayer insulating film 330 are formed by photoresist and etching (in this case, anisotropic etching) (see FIG. 13B); a variable resistance film 326 is deposited on the plug 324 exposed from the base hole 330a, and the interlayer insulating film 330 including a sidewall of the base hole 330a so that the base hole 330a is not completely filled; a bit line wiring 327 that serves as an upper electrode is deposited on the variable resistance film 326; a part of the material composing the bit line wiring 327 and a part of the variable resistance film 326 are removed by photoresist and etching (see FIG. 13C); after that, an interlayer insulating film 328 is deposited on the interlayer insulating film 330 including the bit line wiring 327 and the variable resistance film 326 (see FIGS. 12A and 12B).

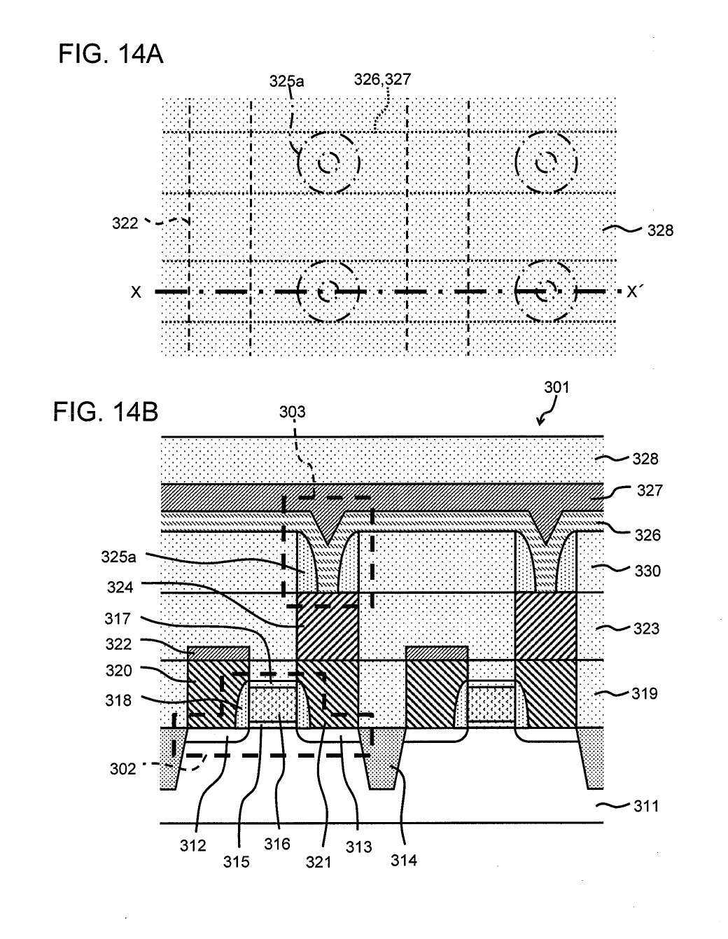

In order that an area of a variable resistance film sandwiched between electrodes is narrowed without oxidizing sidewall portions of a lower electrode and an upper electrode, a variable resistance element 303 shown in FIGS. 14A and 14B was also considered. That is, base holes (base hole without a taper shape) reaching the plug 324 are formed in the interlayer insulating film 330 on the plug 324 that serves as a lower electrode; a sidewall insulating film 325a with a ring shape that covers part of the plug 324 exposed from the base hole and a sidewall of the base hole is formed; a variable resistance film 326 is formed on the interlayer insulating film 330 including the plug 324 exposed from the inside of the sidewall insulating film 325a and the sidewall insulating film 325a so that the inside of the sidewall insulating film 325a is not completely filled; a bit line wiring 327 that serves as an upper electrode is formed on the variable resistance film 326. Part of the variable resistance film 326 is structured to be embedded into the inside of the sidewall insulating film 325a. The bit line wiring 327 that serves as an upper wiring is embedded into on the variable resistance film 326 at the base hole 330a.

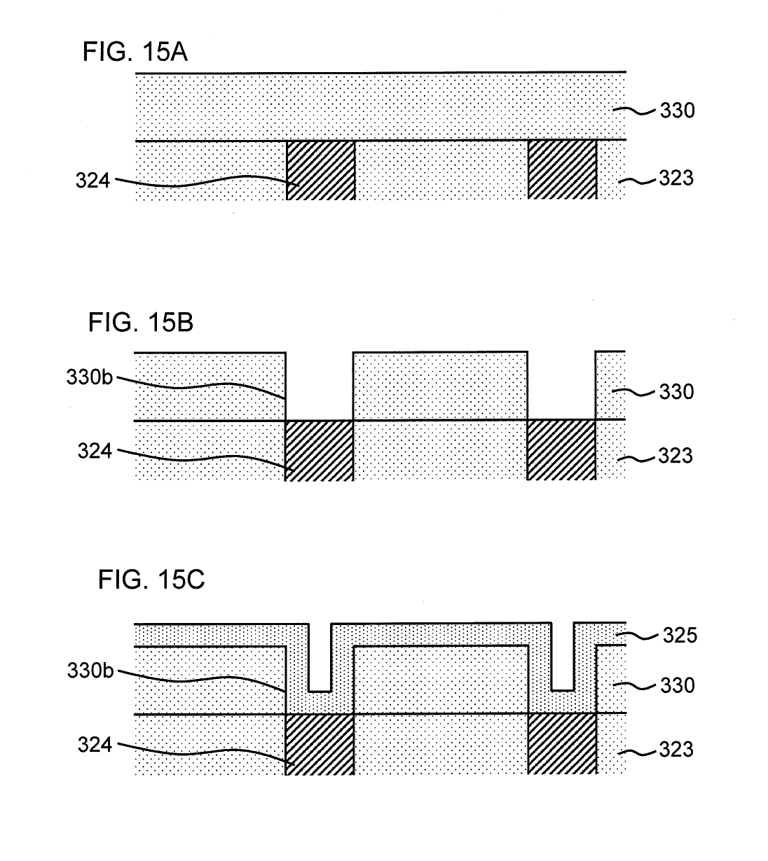

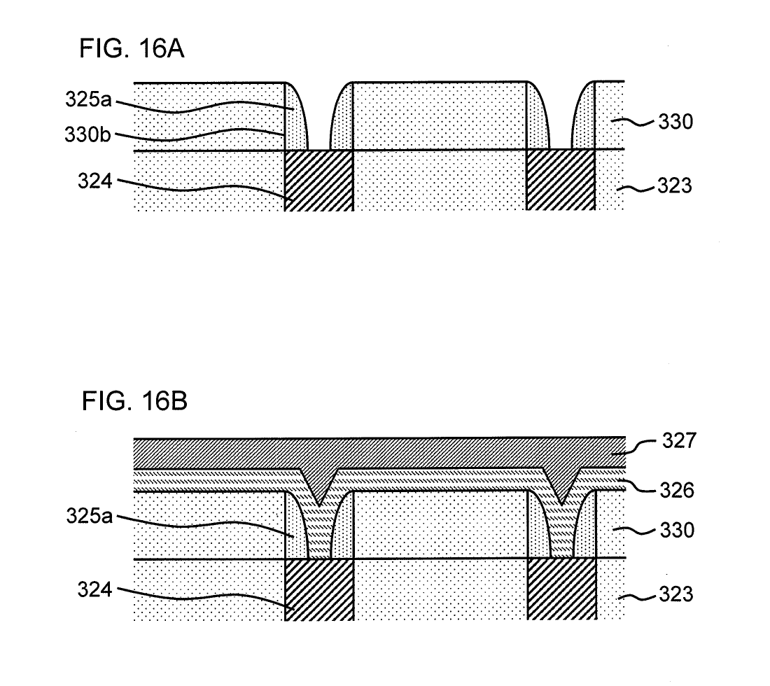

The variable resistance element 303 having a structure shown in FIGS. 14A and 14B can be formed as follows. First, by means of a publicly known method, a semiconductor substrate 311, on which element isolation regions 314, transistors 302, an interlayer insulating film 319, source/drain plugs 320, 321, source wirings 322, an interlayer insulating film 323, and plugs 324 are formed, is provided. After that, an interlayer insulating film 330 is deposited on the interlayer insulating film 323 including plugs 324 (see FIG. 15A); base holes 330b reaching the plugs 324 in the interlayer insulating film 330 are formed by photoresist and etching (in this case, anisotropic etching) (see FIG. 15B); insulating film 325 having a high selective etching ratio for the interlayer insulating film 330 is deposited on the interlayer insulating film 330 including the plug 324 exposed from the base hole 330b and a sidewall of the base hole 330b (see FIG. 15C); sidewall insulating film 325a with a ring shape that covers part of the plug 324 and a sidewall of the base hole 330b is formed by performing an etching back the insulating film 325 (see FIG. 16A); a variable resistance film 326 is deposited so that the inside of the sidewall insulating film 325a is not completely filled; a bit line wiring 327 that serves as an upper electrode on the variable resistance film 326; a part of the material composing the bit line wiring 327 and a part of the variable resistance film 326 are removed by photoresist and etching (see FIG. 16B); after that, an interlayer insulating film 328 is deposited on the interlayer insulating film 330 including the bit line wiring 327 and the variable resistance film 326 (see FIGS. 14A and 14B).

According to the variable resistance element 303 having a structure described by referring to FIGS. 14A to 16B mentioned above, an area of a portion in which the plug 324 that serves as a lower electrode contacts with the variable resistance film 326 can be small (narrowed), which makes it possible that a structure, in which an area of the variable resistance film 326 sandwiched between electrodes (between the plug 324 that serves as a lower electrode and the bit line wiring 327 that serves as an upper electrode) at the variable resistance element 303 is small (narrowed), can be realized without relying on oxidization process of electrodes. Therefore, in a structure where electric field concentration is generated at a limited portion so that dispersion of current paths can be suppressed, an influence of variability in the processes can be reduced. As for the upper electrode, a sharpened portion of the upper electrode corresponds to a portion where electric field concentration is generated. This makes it possible to stabilize Set/Reset characteristics of ReRAM.

However, in the process forming the variable resistance element 303 having the above structure, the variable resistance film 326 and the bit line wiring 327 that serves as an upper electrode are deposited in the base hole (330a in FIG. 13B, 330b in FIG. 15C) that was formed by photoresist and etching in the interlayer insulating film 330 on the plug 324 that serves as a lower electrode. Thus, forming the base holes (330a in FIG. 13B, 330b in FIG. 15B) is not self-aligning to the plug 324 that serves as a lower electrode. In other words, steps of forming an intentional structure, in which an area of the variable resistance film 326 sandwiched between electrodes (between the plug 324 that serves as a lower electrode and a bit line wiring 327 that serves as an upper electrode) is small (narrowed), are not self-aligning to the plug 324 that serves as a lowered electrode.

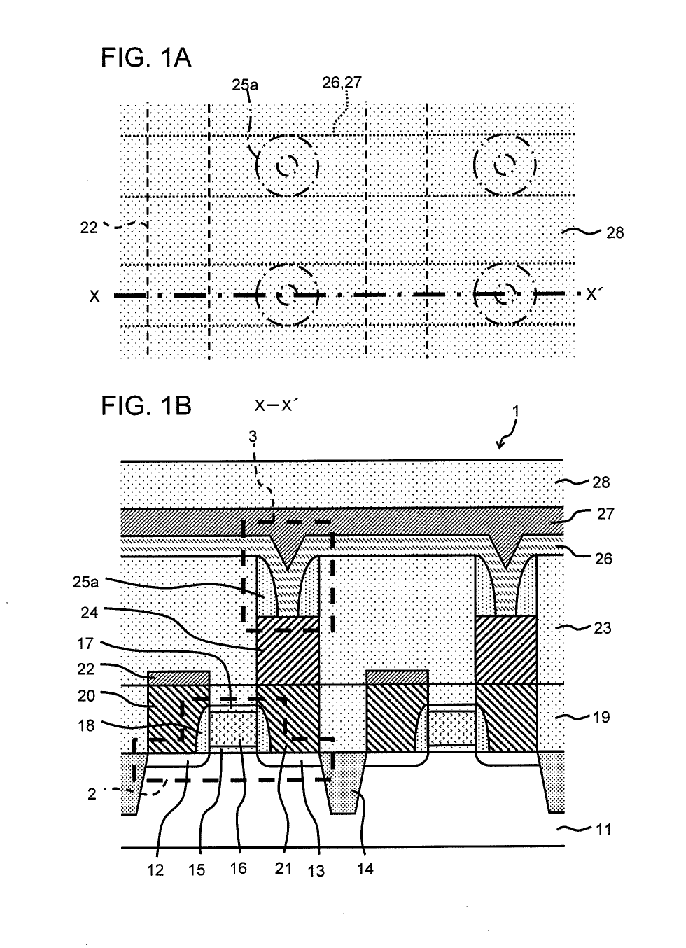

Therefore, it is necessary to set another scope for improvement in the following viewpoints: an influence due to miss-alignment (miss-alignment of the base hole to the plug 324) derived from miniaturization of memory elements is suppressed; the manufacturing processes of a semiconductor device including ReRAM is simplified. An exemplary embodiment of the present disclosure will be described below by referring to the drawings. FIGS. 1 A and 1B are respectively a plan view and a cross-sectional view taken along the line X-X′ schematically showing a structure of a semiconductor device in accordance with the exemplary embodiment of the present disclosure.

A semiconductor device 1 of FIGS. 1A and 1B is a semiconductor device including ReRAM. The semiconductor device 1 includes variable resistance elements 3 in which a significant change of an electric resistance caused by applying a voltage is used, and transistors 2 that control switching of the variable resistance elements 3.

In the semiconductor device 1, element isolation regions 14 (e.g., LOCOS, trench isolation) that electrically isolates between elements (transistors 2) are formed in a semiconductor substrate 11 (e.g., silicon substrate). In the semiconductor device 1, a gate insulating film 15 (e.g., silicon dioxide film), a gate electrode 16 (e.g., polysilicon), and an insulating film 17 (e.g., silicon dioxide film) are laminated one by one as a transistor 2 on a channel of a semiconductor substrate 11 at a region that is surrounded by element isolation regions 14; sidewall insulating films 18 (e.g., silicon nitride film) that cover sidewall surfaces of both sides of laminated body which consists of the gate insulating film 15, the gate electrode 16, and the insulating film 17 are formed; source/drain regions 12, 13 in which impurity is diffused are formed on the semiconductor substrate 11 at both sides of the channel. The gate electrode 16 is electrically connected to a word line driver (not shown) that controls a voltage of a word line.

In the semiconductor device 1, an interlayer insulating film 19 (e.g., silicon dioxide film) is formed on the semiconductor substrate 11 including the transistors 2 and the element isolation regions 14. In the semiconductor device 1, base holes reaching source/drain regions 12, 13 are formed in the interlayer insulating film 19; source/drain plug 20 (e.g., tungsten) is embedded in the base hole reaching source/drain region 12; source/drain plug 21 (e.g., tungsten) is embedded in the base hole reaching source/drain region 13. In the semiconductor device 1, a source wiring 22 (e.g., copper) connected to the source/drain plug 20 is formed on a predetermined region of the interlayer insulating film 19. The source wiring 22 is electrically connected to the source/drain region 12 of the transistor 2 via the source/drain plug 20, and is also electrically connected to a source line driver (not shown) that controls a voltage of the source wiring 22.

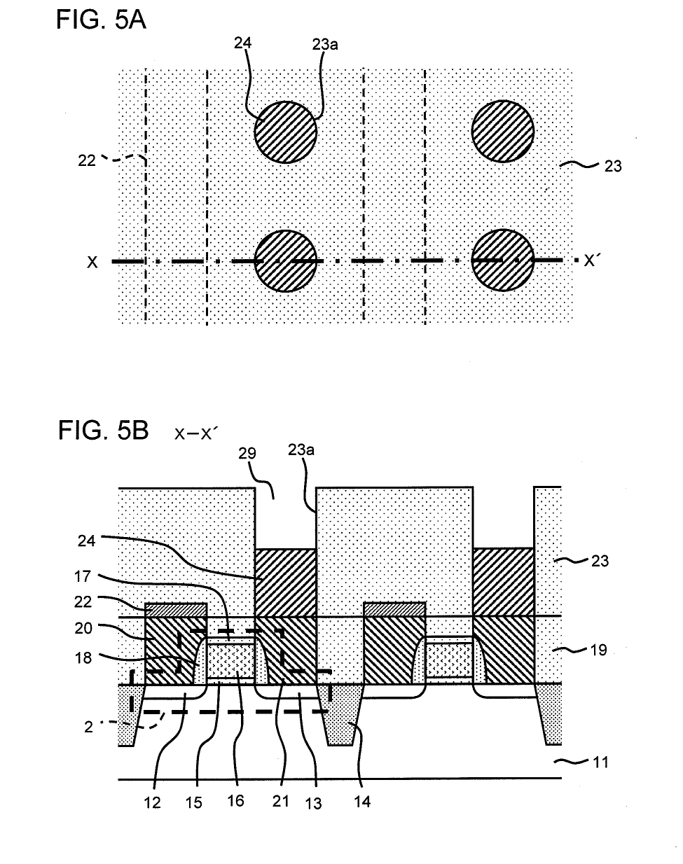

In the semiconductor device 1, an interlayer insulating film 23 (first insulating film; e.g., silicon dioxide film) is formed on the interlayer insulating film 19 including the source wirings 22 and the source/drain plugs 21. The interlayer insulating film 23 is made of an integrally formed insulating material with no joint. The semiconductor device 1 includes base holes (23a in FIGS. 5A and 5B) reaching the source/drain plug 21 in the interlayer insulating film 23, and a plug 24 (conductive plug; e.g., Hf) is embedded in the base hole (23a in FIGS. 5A and 5B) until a position of a predetermined depth from a top surface of the interlayer insulating film 23. That is, the plug 24 is embedded at a predetermined region (region in which the base hole 23a is disposed) between a bottom surface of the interlayer insulating film 23 and a position of a predetermined depth from the top surface of the interlayer insulating film 23. The plug 24 serves as a lower electrode of the variable resistance element 3, and is electrically connected to the source/drain region 13 of the transistor 2 via the source/drain plug 21. The semiconductor device 1 includes a recess (hole portion; 29 in FIGS. 5A and 5B) which has a top surface of the plug 24 as a bottom surface of the recess, and the interlayer insulating film 23 (wall surface of the base hole 23a) as a sidewall of the recess at a region in which the plug 24 is disposed. In the semiconductor device 1, a sidewall insulating film 25a (e.g., silicon nitride film) with a ring shape that covers a sidewall (wall surface of the base hole 23a) of the recess (29 in FIGS. 5A and 5B) and exposes a part of the bottom surface (plug 24) of the recess (29 in FIGS. 5A and 5B) is formed. In the semiconductor device 1, a variable resistance film 26 (e.g., HfO₂) and a bit line wiring 27 (conductive wiring; e.g., Hf) that conformally (in a shape-keeping fashion, i.e. in a state where a cavity shape is kept) cover the sidewall insulating film 25a and the bottom surface of the recess 29 are laminated one by one on a predetermined position of the interlayer insulating film 23 including the plug 24 and the sidewall insulating film 25a at the recess (29 in FIGS. 5A and 5B). In the semiconductor device 1, the variable resistance film 26 does not fill the recess (29 in FIGS. 5A and 5B), and the bit line wiring 27 is formed on the cavity having a sharpened structure of the variable resistance film 26 formed on a region of the recess (29 in FIGS. 5A and 5B). An area of a portion in which the variable resistance film 26 contacts with the plug 24 that serves as a lower electrode becomes small (narrow) by the sidewall insulating film 25a. The bit line wiring 27 serves as an upper electrode of the variable resistance element 3, and is electrically connected to a sense amplifier (not shown) that amplifies a voltage. In the semiconductor device 1, an interlayer insulating film 28 (e.g., silicon dioxide film) is formed on the interlayer insulating film 23 including the bit line wiring 27 and the variable resistance film 26.

Meanwhile, type of material of each constituent element in the above explanation is not limited to the presented example. For instance, materials capable of varying a resistance state in response of magnitude of applied voltage such as ZrO₂, Al₂O₃, TiO₂, Ta₃O₅, NiO, CoO, and CuO other than HfO₂ can be used for the variable resistance film 26. And conductive materials such as Zr, Ti, TiN, Ni, Co, and a laminated film consisting of some of those materials other than Hf can be used for the plug 24 that serves as a lower electrode and the bit line wiring 27 that serves as an upper electrode. And the sidewall insulating film 25a is not limited to a silicon nitride film, and insulating materials with a high etching selection ratio for the interlayer insulating film 23 can be used for the sidewall insulating film 25a.

Next, an operation of a semiconductor device in accordance with the exemplary embodiment of the present disclosure will be described.

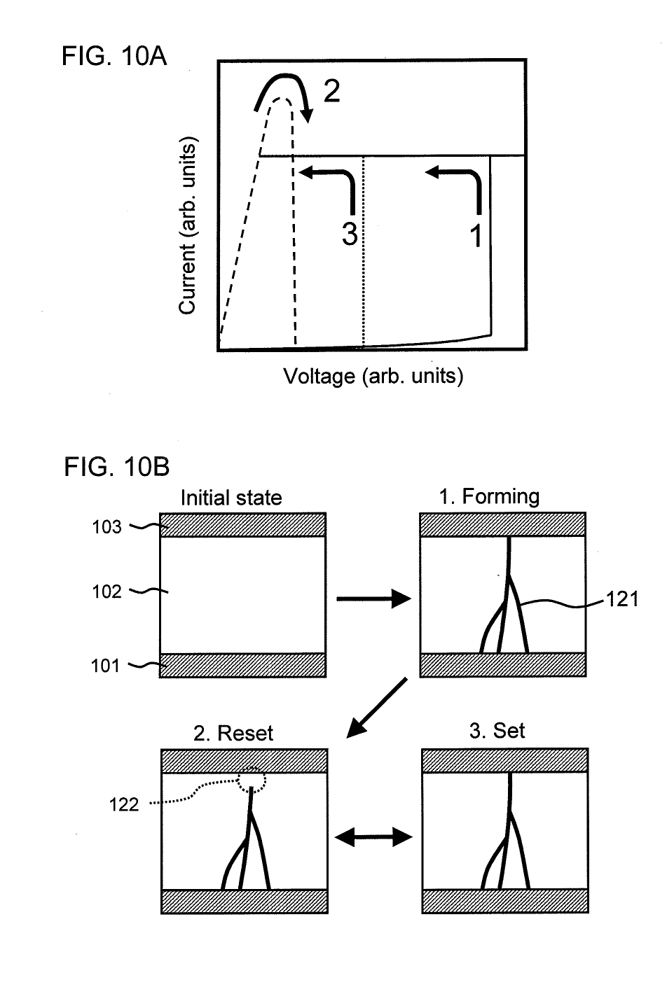

First, when Forming, a current path (corresponding to 121 in 1. Forming of FIG. 10B) which is conducted between the plug 24 that serves as a lower electrode and the bit line wiring 27 that serves as an upper electrode is formed in the variable resistance film 26 by applying positive voltages to the source wiring 22 and the gate electrode 16 in initial state (corresponding to Initial state in FIG. 10B) in which current paths are not formed in the variable resistance film 26, so that the variable resistance film 26 becomes a low resistance state.

When performing a Reset, the current path (corresponding to 121 in 1. Forming of FIG. 10B) is ruptured at a portion near the bit line wiring 27 by applying a lower positive voltage than voltage applied when performing a Set (when Forming) to the source wiring 22, and applying a positive voltage to the gate electrode 16 in a low resistance state after the Forming (corresponding to 1. Forming of FIG. 10B), so that the variable resistance film 26 is switched from the low resistance state to a high resistance state (corresponding to 2. Reset in FIG. 10B).

When performing a Set, the rupture at the portion near the bit line wiring 27 vanishes by applying a higher positive voltage than the applied voltage when performing a Reset to the source wiring 22, and applying a positive voltage to the gate electrode 16 in a high resistance state (corresponding to 2. Reset in FIG. 10B), so that the variable resistance film 26 is switched from the high resistance state to a low resistance state (corresponding to 3. Set in FIG. 10B).

Meanwhile, while performing a Forming, a Reset, or a Set, the current is limited in response to a saturated current value of the transistor 2 controlled by adjusting the voltage applied to the gate electrode 16 in order that the variable resistance film 26 becomes a desired resistance value. While Forming, a positive voltage may be applied to the bit line wiring 27 instead of the source wiring 22.

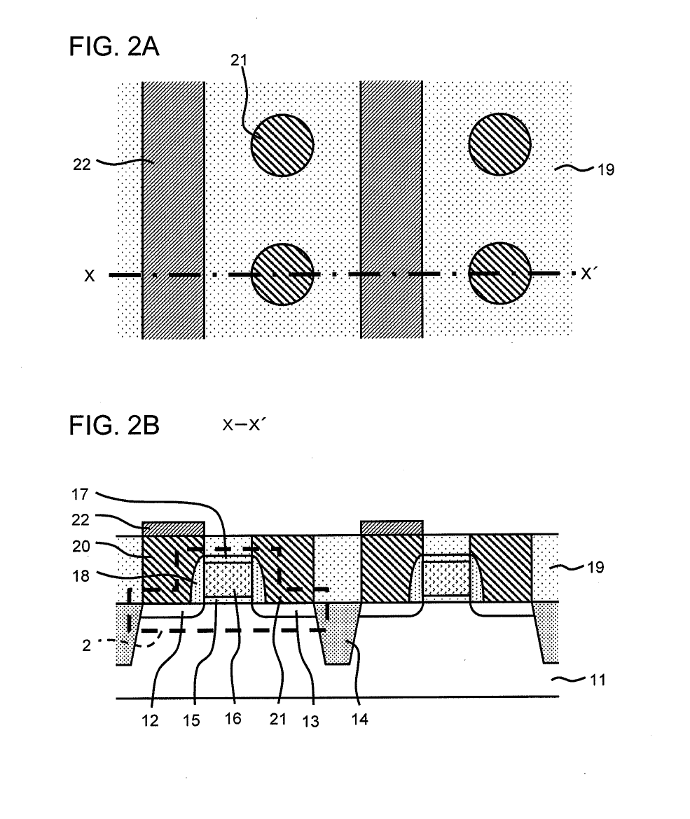

Next, a method for manufacturing a semiconductor device in accordance with the exemplary embodiment of the present disclosure will be described by referring to the drawings. FIGS. 2A to 8B are views schematically showing respective steps of the method for manufacturing a semiconductor device in accordance with the exemplary embodiment of the present invention, in each one of which FIGS. 2A, 3A, 4A, 5A, 6A, 7A and 8A are plan views; FIGS. 2B, 3B, 4B, 5B, 6B, 7B and 8B are cross-sectional views taken along the line X-X′.

A variable resistance element 3 having a structure as shown in FIGS. 1A and 1B can be formed as follows. First, by means of a publicly known method, a semiconductor substrate 11 (substrate), on which element isolation regions 14, transistors 2, an interlayer insulating film 19, source/drain plugs 20, 21, source wirings 22 are formed, is provided (see FIGS. 2A and 2B). For instance, the element isolation regions 14 are formed at predetermined positions on the semiconductor substrate 11; after that, a gate electrode 16 is formed on the semiconductor substrate 11 via a gate insulating film 15 by depositing and performing an etching the gate insulating film 15, the gate electrode 16, and the insulating film 17 one by one on the semiconductor substrate 11 including the element isolation regions 14; after that, a sidewall insulating films 18 are formed at both sides of a laminator body consisting of the gate insulating film 15, the gate electrode 16, and the insulating film 17; after that, source/drain regions 12, 13 are formed by implanting impurity into parts of the semiconductor substrate 11 beside and below the gate electrode 16; after that, an interlayer insulating film 19 is formed; after that, source/drain plugs 20, 21. that are respectively connected to the source/drain regions 12, 13 by penetrating the interlayer insulating film 19 are formed; after that, a source wiring 22 is formed that is connected to the source/drain plug 20.

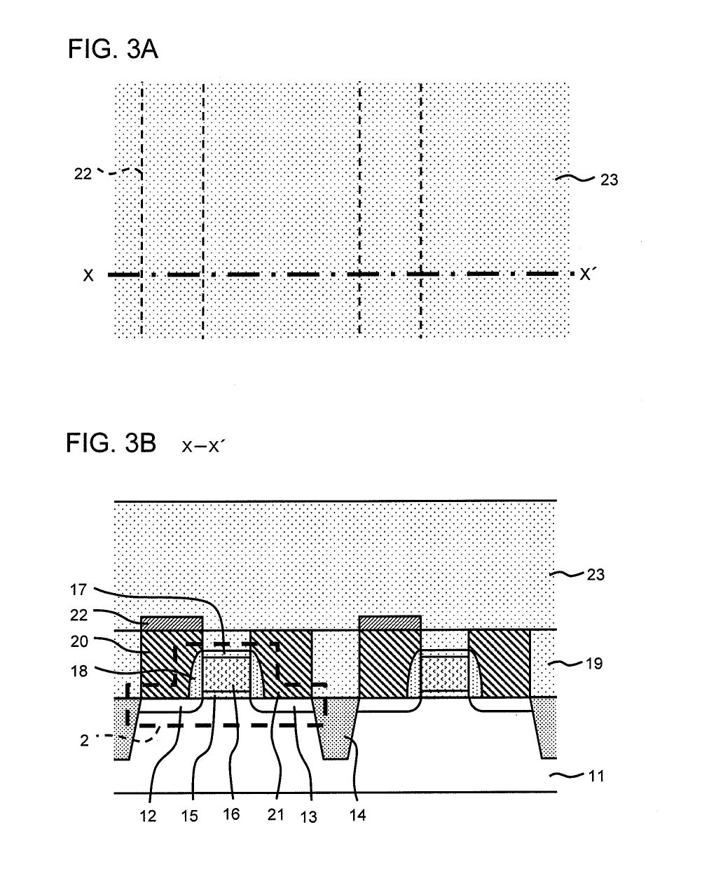

Next, an interlayer insulating film 23 (first insulating film) that covers the semiconductor substrate 11 (including the element isolation regions 14, the transistors 2, the interlayer insulating film 19, the source/drain plugs 20, 21, and the source wirings 22) is formed (see FIGS. 3A and 3B). For instance, an interlayer insulating film 23 is deposited on the interlayer insulating film 19 including the source/drain plugs 20, 21 and source wirings 22 by means of CVD (Chemical Vapor Deposition) or the like.

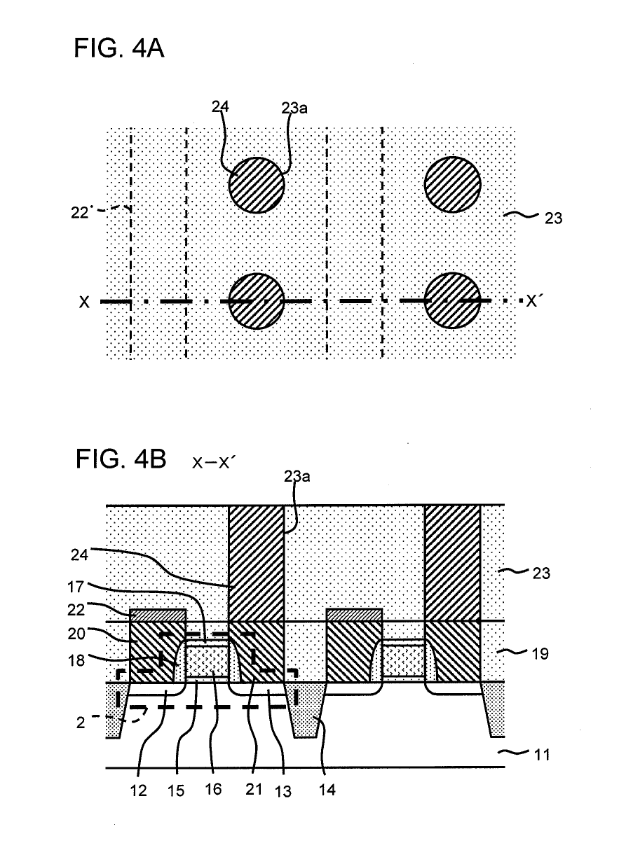

Next, a plug 24 (conductive plug) that penetrates the interlayer insulating film 23 is formed (see FIGS. 4A and 4B). For instance, a base hole 23a reaching the source/drain plug 21 is formed in the interlayer insulating film 23 by means of lithography and etching (in this case, anisotropic etching); after that, a plug 24 that serves as a lower electrode is formed in the base hole 23a by means of growth of conductive film and CMP (Chemical Mechanical Polishing). By this step, the plug 24 is electrically connected to the source/drain region 13 via the source/drain plug 21.

Next, by partly removed an upper part of the plug 24, a recess 29 (hole portion) that has a top surface of the plug 24 as a bottom surface of the recess and a portion of the partly removed interlayer insulating film 23 that covered the plug 24 as a sidewall of the recess is formed on the plug 24 (see FIGS. 5A and 5B). For instance part (upper part) of the plug 24 in the base hole 23a is removed by performing an anisotropic etching (etching back not using photoresist) of the plug 24 that is exposed on the surface of the interlayer insulating film 23, so that the recess 29 that has the top surface of the. plug 24 as a bottom surface of the recess and the surface of the base hole 23a in the interlayer insulating film 23 as a sidewall of the recess is formed. Meanwhile, since the recess 29 is formed by performing an etching back the top surface of the plug 24 embedded into the base hole 23a in the interlayer insulating film 23, the recess 29 can be formed in a self-alignment manner for the plug 24 that serves as a lower electrode.

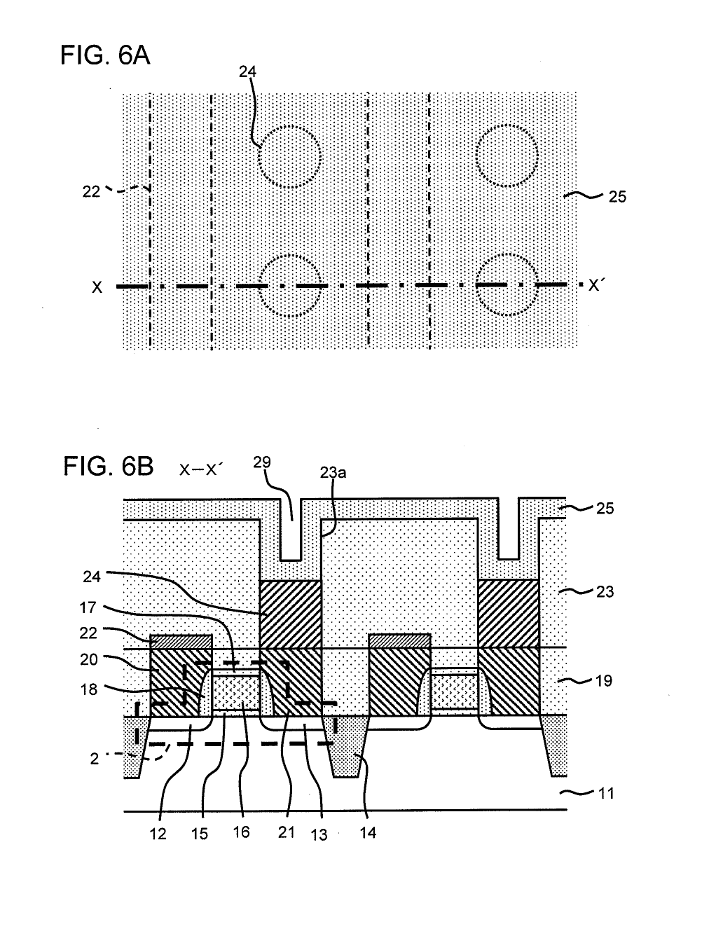

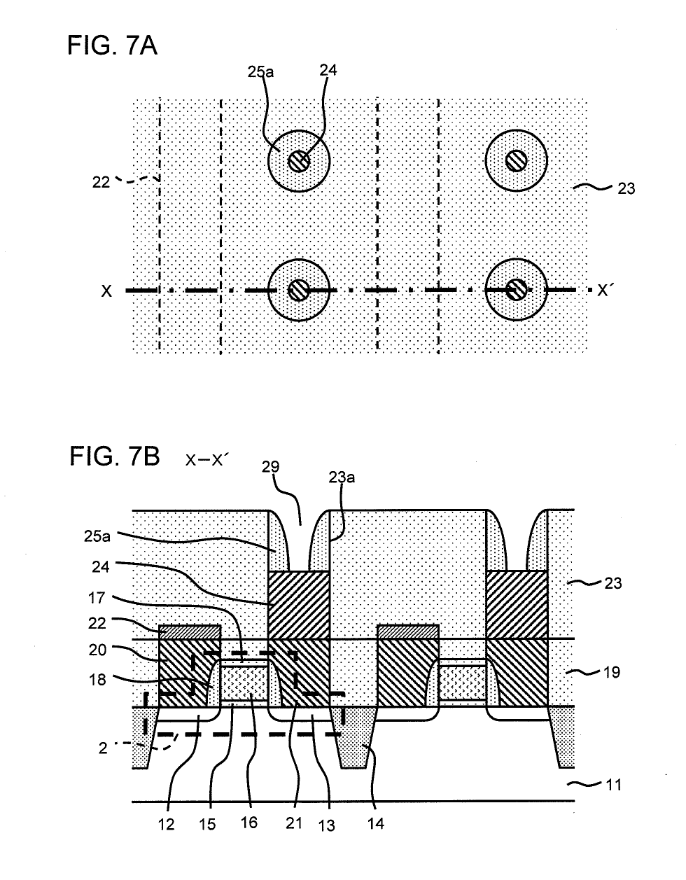

Next, a sidewall insulating film 25a, which exposes a part of the bottom surface of the recess 29 while covering the sidewall and the bottom portion of the recess 29, is formed (see FIGS. 7A and 7B). Here, when forming the sidewall insulating film 25a, for instance, an insulating film 25 is deposited on the interlayer insulating film 23 including the recess 29 by means of CVD or the like. (see FIGS. 6A and 6B); after that, the sidewall insulating film 25a is formed by performing an anisotropic etching the insulating film (25 in FIGS. 6A and 6B). Meanwhile, a material having a high selective etching ratio for the interlayer insulating film 23 is used for the insulating film 25. The sidewall insulating film 25a covers a sidewall of the recess 29 (surface of the base hole 23a), and is formed in a ring shape so that a part of the bottom surface of the recess 29 (plug 24) is exposed. Since the sidewall insulating film 25a is formed by depositing the insulating film (25 in FIGS. 6A and 6B) and then performing anisotropic etching, the sidewall insulating film 25a is formed in a self-alignment manner for the sidewall of recess 29.

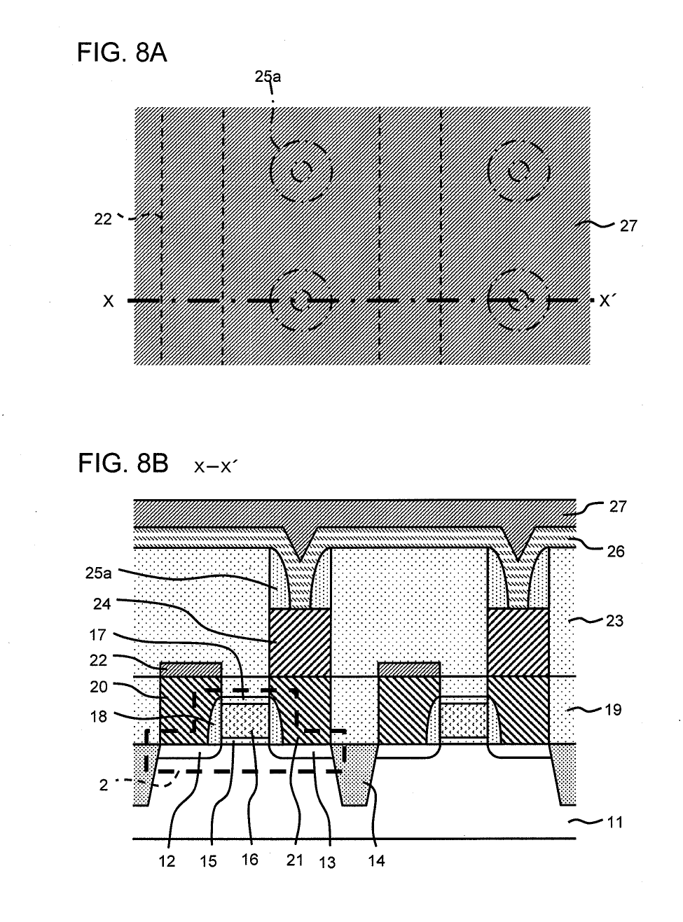

Next, a variable resistance film 26 that covers the sidewall insulating film 25a and the bottom surface (the top surface of the plug 25) of the recess 29 is formed; after that, a conductive film 27 that covers the variable resistance film 26 is formed (see FIGS. 8A and 8B). For instance, the variable resistance film 26 is formed (deposited) by means of CVD or the like. so that the recess 29 is not embedded completely on the interlayer insulating film 23 including the plug 24 and the sidewall insulating film 25a at the recess 29, and the cavity is remained at the upper part of the recess 29; after that, the conductive film (bit line wiring 27) that serves as an upper electrode is deposited so that the cavity of the upper part of the recess 29 is embedded on the variable resistance film 26 by means of growth of conductive film (see FIGS. 8A and 8B). At this time, a portion of the bit line wiring 27 that serves as an upper electrode disposed nearest the plug 24 that serves as a lower electrode has a sharpened structure.

And after that, the bit line wiring 27 is formed by removing the conductive film (bit line wiring 27) and the variable resistance film 26 of unnecessary portions by means of photoresist and etching; lastly, an interlayer insulating film 28 is deposited on the interlayer insulating film 23 including the bit line wiring 27 and the variable resistance film 26 by means of CVD or the like. (see FIGS. 1A and 1B). Meanwhile, a wiring process or the like after that is performed by means of a publicly known method.

According to the present exemplary embodiment, an area of the variable resistance film 26 of a portion sandwiched between electrodes (between the plug 24 that serves as a lower electrode and the bit line wiring 27 that serves as an upper wiring) can be narrowed in a self-alignment manner for the plug 24 by forming the recess (29 in FIGS. 5A and 5B) and the sidewall insulating film 25a on the plug 24 that serves as a lower electrode without relying on a fabrication process by etching using photoresist, which makes it possible to form a structure in which a voltage is applied to a limited portion of the variable resistance film 26. As a result, dispersion of current paths that are formed while Forming can be suppressed, which makes it possible to avoid variability in characteristics of elements and stabilize a Set/Reset operation of the variable resistance element 3 in accordance with ReRAM.

According to the present exemplary embodiment, since a structure in which an area of the variable resistance film 26 portion sandwiched between electrodes (between the plug 24 that serves as a lower electrode and the bit line wiring 27 that serves as an upper electrode) is narrowed can be realized without relying on etching of the variable resistance film 26, a dispersion of current paths due to etching damage of the variable resistance film 26 is avoided, which makes it possible to reduce variability of characteristics of the elements.

According to the present exemplary embodiment, a structure in which an area of the variable resistance film 26 of a portion sandwiched between electrodes (between the plug 24 that serves as a lower electrode and the bit line wiring 27 that serves as an upper electrode) is narrowed can be realized without relying an oxidization process of the electrodes, which makes it possible to reduce variability in characteristics due to variability in thickness of oxidized film at peripheral portions of the electrodes. Besides, since it is unnecessary to oxidize the electrodes, selection of material for the electrodes is not limited.

Besides, according to the present exemplary embodiment, the recess (29 in FIGS. 5A and 5B), sidewall insulating film 25a, and the variable resistance film 26 can be formed in a self-alignment manner for the plug 24 that serves as a lower electrode, which make it possible to reduce an influence of miss-alignment derived from miniaturization of elements.

Besides, according to the present exemplary embodiment, the variable resistance element 3 can be formed without relying on fabrication process by etching using photoresist, which makes it possible to simplify manufacturing processes.

Besides, according to the present exemplary embodiment, a structure of electric field concentration in which the bit line wiring 27 that serves as an upper electrode is sharpened is used, which makes it possible to prevent unnecessary current paths from being formed when Forming. Thus, current paths formed in the variable resistance film 26 become a single path that is an ideal state, which makes it possible to reduce variability in performance of memory elements, and prevent from causing a significant deterioration in reliability.

In summary, according to the present disclosure, a hole portion and a sidewall insulating film are formed on a conductive plug that serves as a lower electrode without relying on a fabrication process by etching using photoresist, which makes it possible that an area of the variable resistance film of a portion sandwiched between electrodes (between the conductive plug that serves as a lower electrode and a conductive film that serves as an upper electrode) is narrowed for the lower electrode in a self-alignment manner, so that a structure in which a voltage is applied to the variable resistance film at a limited portion can be formed. Furthermore, in case where drawing reference symbols are denoted in the present application, the drawing reference symbols are shown only in order to assist understanding, and are not intended to limit the present invention to embodiments of the drawings.

The exemplary embodiments and examples may include variations and modifications without departing the gist and scope of the present invention as disclosed herein and claimed as appended herewith, and furthermore based on the fundamental technical spirit. It should be noted that any combination and/or selection of the disclosed elements may fall within the claims of the present invention. That is, it should be noted that the present invention of course includes various variations and modifications that could be made by those skilled in the art according to the overall disclosures including claims and drawings, and technical spirit.

What is claimed is:

1. A method for manufacturing a semiconductor device, comprising:
forming a first insulating film that covers a substrate;
forming a conductive plug that penetrates the first insulating film;
forming a hole portion on the conductive plug by partly removing upper part of the conductive plug, wherein the hole portion has a top surface of the conductive plug as a bottom surface of the hole portion, and has the first insulating film of a portion that covered the partly removed conductive plug as a sidewall of the hole portion;
forming a sidewall insulating film that exposes a part of the bottom surface of the hole portion while covering the sidewall and a bottom portion of the hole portion;
forming a variable resistance film that covers the sidewall insulating film of the hole portion and the bottom surface of the hole portion; and
forming a conductive film that covers the variable resistance film.

2. The method for manufacturing a semiconductor device according to claim 1, wherein
in the forming the variable resistance film, the variable resistance film is formed so that a cavity is left at upper part of the hole portion by embedding the hole portion incompletely; and
in the forming the conductive film, the conductive film is formed so that the cavity of the upper part of the hole portion is embedded completely.

3. The method for manufacturing a semiconductor device according to claim 1, wherein
in the forming the hole portion, upper part of the conductive plug is partly removed by performing anisotropic etching the conductive plug exposed on a surface of the first insulating film, so that the hole portion is formed.

4. The method for manufacturing a semiconductor device according to claim 1, wherein
in the forming the sidewall insulating film, after forming a second insulating film that covers the sidewall and the bottom surface of the hole portion, the sidewall insulating film is formed by performing anisotropic etching the second insulating film.

5. The method for manufacturing a semiconductor device according to claim 1, further comprising before the forming the first insulating film:
forming a gate electrode on the substrate via a gate insulating film; and
forming source/drain regions by implanting impurity into parts of the substrate beside and below the gate electrode,
wherein the forming the conductive plug, the conductive plug is formed so as to contact with the source/drain region by penetrating the first insulating film.

6. A semiconductor device comprising:
a first insulating film that covers a substrate;
a conductive plug that is embedded between a bottom surface of the first insulating film and a position of a predetermined depth from a top surface of the first insulating film at a predetermined region of the first insulating film;
a hole portion on the conductive plug that has a top surface of the conductive plug as a bottom surface of the hole portion, and has the first insulating film as a sidewall of the hole portion at a region in which the conductive plug is disposed;
a sidewall insulating film that covers the sidewall of the hole portion, and covers a part of the bottom surface of the hole portion;
a variable resistance film that covers the sidewall insulating film and the bottom surface of the hole portion; and
a conductive film that covers the variable resistance film.

7. The semiconductor device according to claim 6, comprising a transistor that has a gate electrode via a gate insulating film on the substrate and source/drain regions in which impurity is implanted into parts of the substrate beside and below the gate electrode, wherein the conductive plug is electrically connected to a predetermined the source/drain region.

8. The semiconductor device according to claim 6, wherein
the variable resistance film is formed so that a cavity is left at upper part of the hole portion,
the conductive film is formed so that the cavity of the upper part of the hole portion is embedded completely.

9. The semiconductor device according to claim 6, wherein the first insulating film is made of an integrally formed insulating material with no joint.

10. The semiconductor device according to claim 7, wherein
the source/drain region, which is not electrically connected to the conductive plug, is electrically connected to a source line driver that controls a voltage via a source line;
the gate electrode is electrically connected to a word line driver that controls a voltage via a word line; and
the conductive film is electrically connected to a sense amplifier that amplifies a voltage.

11. A semiconductor device, comprising:
having a hole portion;
at a region in which a conductive plug is disposed, having a top surface of the conductive plug as a bottom surface of the hole portion;
having an insulating film in which the conductive plug is formed as a sidewall of the hole portion;
a sidewall insulating film that covers the sidewall of the hole portion, and covers part of the bottom surface of the hole portion(s);
a variable resistance film that covers the sidewall insulating film and the bottom surface of the hole portion;
a conductive film that covers the variable resistance film.

12. The semiconductor device according to claim 11, comprising a transistor that has a gate electrode via a gate insulating film on the substrate and source/drain regions in which impurity is implanted into parts of the substrate beside and below the gate electrode,
wherein the conductive plug is electrically connected to a predetermined the source/drain region.

13. The semiconductor device according to claim 11, wherein
the variable resistance film is formed so that a cavity is left at upper part of the hole portion,
the conductive film is formed so that the cavity of the upper part of the hole portion is embedded completely.

14. The semiconductor device according to claim 11,
wherein the first insulating film is made of an integrally formed insulating material with no joint.

15. The semiconductor device according to claim 12, wherein
the source/drain region, which is not electrically connected to the conductive plug, is electrically connected to a source line driver that controls a voltage via a source line;
the gate electrode is electrically connected to a word line driver that controls a voltage via a word line; and
the conductive film is electrically connected to a sense amplifier that amplifies a voltage.

16. The semiconductor device according to claim 6, wherein
a material of the variable resistance film is HfO₂.

17. The semiconductor device according to claim 6, wherein
the material of the variable resistance film is one of ZrO₂, Al₂O₃, TiO₂, Ta₃O₅, NiO, CoO, and CuO other than HfO₂.

18. The semiconductor device according to claim 11, wherein
a material of the variable resistance film is HfO₂.

19. The semiconductor device according to claim 11, wherein
the material of the variable resistance film is one of ZrO₂, Al₂O₃, TiO₂, Ta₃O₅, NiO, CoO, and CuO other than HfO₂.
